(19) United States
(12) Patent Application Publication
(10) Pub. No.: US 2026/0179888 A1
(43) Pub. Date: Jun. 25, 2026

(54) PLASMA GENERATION APPARATUS

(71) Applicant: Beijing E-Town Semiconductor Technology Co., Ltd., Beijing (CN)

(72) Inventors: Changle GUAN, Beijing (CN); Qiang FAN, Beijing (CN); Baocun CHEN, Beijing (CN); Yongming SONG, Beijing (CN); Jiansheng LIU, Beijing (CN)

(21) Appl. No.: 19/428,677

(22) Filed: Dec. 22, 2025

(30) Foreign Application Priority Data
Dec. 24, 2024 (CN) 202411920356.7

(51) Int. Cl. H01J 37/32

(52) U.S. Cl. CPC H01J 37/32522; H01J 37/32477; H01J 37/32513; H01J 2237/334

(57) ABSTRACT

Provided is a plasma generation apparatus including a dielectric tube, a coil and a liner. A first end of the dielectric tube in an axial direction is connected with a cover plate and a second end is communicated with a chamber; the coil is wound outside the dielectric tube; the liner is disposed on an inner side of the dielectric tube and extends along an inner wall of the dielectric tube, such that the inner wall of the dielectric tube is at least partially radially shielded by the liner.

### CROSS-REFERENCE TO RELATED APPLICATIONS

The present application claims priority to Chinese Patent Application No. CN202411920356.7, filed with the China National Intellectual Property Administration on Dec. 24, 2024, the disclosure of which is hereby incorporated herein by reference in its entirety.

### TECHNICAL FIELD

The present disclosure relates to the technical field of semiconductor devices, and in particular, to a plasma generation apparatus.

### BACKGROUND

The dielectric materials exhibit excellent dielectric properties, mechanical strength, and corrosion resistance, and are therefore commonly selected for the dielectric tube to reduce wafer contamination caused by by-products generated in the chamber during processing. When the coil is energized, the plasma density is highest in the region corresponding to the coil. Ions bombard the dielectric tube, and the strong chemical reactivity of excited-state free radicals further accelerates corrosion of the dielectric tube. The dielectric tube can be rapidly consumed especially in hydrogen-containing processes, resulting in increased operating costs and extended equipment downtime for maintenance.

### SUMMARY

An embodiment of the present disclosure provides a plasma generation apparatus to solve or alleviate one or more technical problems in the existing art.

In an aspect of the embodiment of the present disclosure, provided is a plasma generation apparatus including:
a dielectric tube, a first end of the dielectric tube in an axial direction being connected with a cover plate and a second end being in communication with a chamber;
a coil wound outside the dielectric tube; and
a liner disposed on an inner side of the dielectric tube, the liner extending along an inner wall of the dielectric tube such that the inner wall of the dielectric tube is at least partially shielded by the liner in a radial direction.

In an implementation, the liner is a cylindrical structure formed by stacking a plurality of annular members in sequence in the axial direction of the dielectric tube, and a diameter of the annular members is smaller than an inner diameter of the dielectric tube.

In an implementation, two ends of the annular member in the axial direction are provided with a protrusion or an indentation having a matching shape of the protrusion, respectively; any two annular members are connected with each other by engaging the protrusion of one annular member with the indentation of the other annular member.

In an implementation, the chamber is connected to the dielectric tube by a first sinking platform, and a sealing ring is arranged between the first sinking platform and the dielectric tube.

In an implementation, the chamber is connected to the liner by a second sinking platform having a greater sinking depth than the first sinking platform.

In an implementation, the protrusion or the indentation is provided on a side close to a center of the dielectric tube.

In an implementation, the liner is made of ceramic material.

In an implementation, the annular member has a thickness ranging between 1 and 10 mm.

In an implementation, a gap between the annular member and the inner wall of the dielectric tube is smaller than a thickness of the plasma sheath.

In another aspect of the embodiment of the present disclosure, provided is a plasma etching apparatus including the plasma generation apparatus according to any one of the embodiments.

The above technical scheme adopted by the embodiments of the disclosure can protect the dielectric tube, reduce the apparatus consumption and ensure and maintain high etching rate.

The foregoing summary is provided for descriptive purposes only and is not intended to be limiting in any way. In addition to the illustrative aspects, embodiments and features as described above, further aspects, embodiments and features of the present disclosure will become readily apparent by reference to the accompanying drawings and the following detailed description.

### BRIEF DESCRIPTION OF THE DRAWINGS

In the drawings, like reference characters designate like or similar parts or elements throughout the several views, unless otherwise specified. The accompanying figures are not necessarily to scale. It should be understood that the drawings illustrate only certain the embodiments disclosed herein and are not intended to limit the scope of the present disclosure.

FIG. 1 is a schematic diagram of a plasma generation apparatus according to an embodiment of the present disclosure.

FIG. 2 is an enlarged partial diagram of the plasma generation apparatus according to an embodiment of the present disclosure.

### LIST OF REFERENCE NUMERALS

1. a gas inlet line; 2. a cover plate; 3. a seal ring; 4. a dielectric tube; 5. a coil; 6. a chamber; 61. an edge portion; 7. a wafer; 8. a vacuum pump; 9. a liner; 91. an annular member; 92. a protrusion.

### DETAILED DESCRIPTION

Hereinafter, only certain exemplary embodiments will be described briefly. As those skilled in the art will appreciate, the described embodiments may be modified in various ways without departing from the spirit or scope of the present disclosure. Accordingly, the drawings and description are to be considered illustrative in nature and not restrictive.

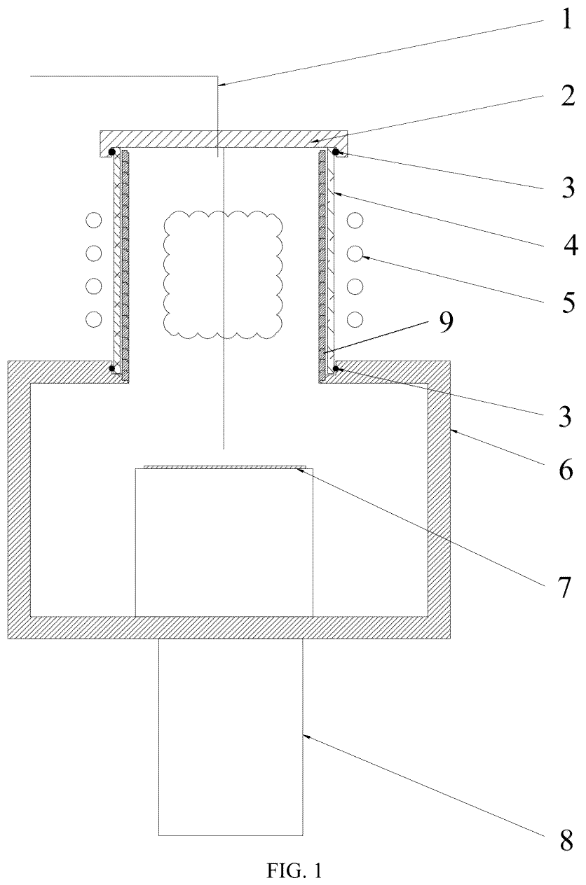

FIG. 1 is a schematic diagram of a plasma generation apparatus according to an embodiment of the present disclosure. As shown in FIG. 1, the apparatus includes:
a dielectric tube 4, a first end of the dielectric tube 4 in an axial direction being connected with a cover plate 2 and a second end being in communication with a chamber 6;
a coil 5 wound outside the dielectric tube 4; and
a liner 9 disposed on an inner side of the dielectric tube 4, the liner 9 extending along an inner wall of the dielectric tube 4 such that the inner wall of the dielectric tube 4 is at least partially shielded by the liner 9 in a radial direction.

In the embodiment of the present disclosure, the dielectric tube 4 is a quartz cylinder. A layer of liner 9 is disposed on the inner wall of the dielectric tube 4 and configured to fully cover the inner wall of the cylinder. The liner 9 may extend from the first end to the second end of the dielectric tube 4 to completely shield the inner wall of the dielectric tube 4. The liner 9 may also be slightly shorter than a length of the inner wall of the dielectric tube 4 to shield most of the inner wall of the dielectric tube 4. Since quartz is susceptible to erosion under the high temperature and chemical reaction conditions, the liner 9 acts as a protective barrier that is able to prevent direct plasma contact with the quartz, thereby minimizing material loss and corrosion.

The cover plate 2 is connected with the dielectric tube 4 through a sealing ring 3, and the cover plate 2 can be in connection with a gas inlet line 1.

According to the scheme of the embodiment of the disclosure, the service life of the dielectric tube 4 can be prolonged, and the maintenance requirement of the apparatus is reduced.

In an implementation, the liner 9 is a cylindrical structure formed by stacking a plurality of annular members 91 in sequence in the axial direction of the dielectric tube 4, and a diameter of the annular members 91 is smaller than an inner diameter of the dielectric tube 4.

In an embodiment of the present disclosure, the plurality of annular members 91 are stacked at a time to form a cylinder of the liner 9 which is disposed on the inner side of the dielectric tube 4. By using the structure in which the plurality of annular members 91 are stacked, a better heat management can be provided for the apparatus. An annular member 91 with high temperature close to the coil 5 can rapidly transfer heat to an adjacent annular member 91 with low temperature, so that the heat is uniformly distributed to avoid local overheating.

According to the scheme of the embodiment of the disclosure, the temperature of the liner 9 can be ensured to be uniform in the whole etching process, the performance fluctuation of the apparatus caused by nonuniform temperature can be reduced, and the stability and the repeatability of the process can be improved.

Since the annular member 91 is independent and can be installed or removed individually, the installation and maintenance process of the liner 9 can be simplified. A gap between the annular members 91 may alleviate stress concentrations caused by thermal expansion, reducing the risk of structural damage due to temperature changes. The gap between the annular members 91 allows etching gas to flow between the liner 9 and the inner wall of the dielectric tube 4, improving gas exchange efficiency during etching.

In an implementation, two ends of the annular member 91 in the axial direction are provided with a protrusion 92 or an indentation having a matching shape with the protrusion, respectively; any two annular members 91 may be connected with each other by engaging the protrusion 92 of one annular member with the indentation of the other annular member.

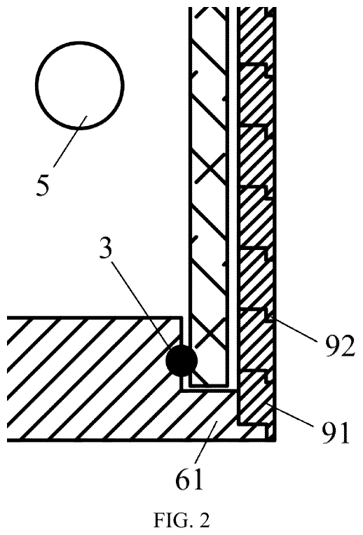

In the embodiment of the disclosure, the shape-matching projection 92 or indentation may be referred to as a “labyrinth structure”. There is a matching labyrinth arrangement between any two annular members 91 as shown in FIG. 2. By means of the cooperation of the protrusion 92 and the indentation, the connection between the annular members 91 becomes tighter, the chance that plasma may leak from the gap between the liner 9 and the dielectric tube 4 to a surface of the dielectric tube 4 is reduced, and the dielectric tube 4 is protected from direct bombardment of the plasma.

The cooperation of the projection 92 and the indentation may provide additional mechanical support, enhancing the overall structural stability of the liner 9.

This configuration increases the contact area between two adjacent annular members 91, which helps to dissipate heat to avoid local overheating. By means of the cooperation of the protrusion 92 and the indentation, heat can be more quickly and more uniformly transferred between the annular members 91.

The tight connection reduces the risk of particles or contaminants entering the chamber 6 from the gap between the liner 9 and the dielectric tube 4.

Possible implementations of the labyrinth structure:
Protrusion-Indentation Fit:
   Two ends in the axial direction of each annular member 91 are provided with a protrusion 92 and an indentation, respectively, which match with each other in shape. The cross-section of the protrusion 92 may be square, hemispherical, triangular, trapezoidal or any other suitable mating shape, and the indentation is correspondingly shaped to accommodate the projection 92.
Screwed Connection:
   The annular member 91 may be designed with a spiral groove or a spiral protrusion, so that adjacent members are tightly connected by screwing to provide better mechanical support.
Labyrinth Groove:
   Labyrinth grooves are formed at the axial ends of the annular member 91, with which adjacent members are nested into one another to form a labyrinth structure.
Tongue-Groove Connection:
   The ends of the annular member 91 in the axial direction are designed with a tongue-shaped projection and a notch, similar to the tongue-and-groove connection in carpenters, to ensure the close fit between the members.
Snap-Fit Connection:
   A latch-like structure is designed such that the annular members 91 are mutually interlocked through snap-fit engagement, ensuring a secure and stable connection
Wavy Constructure:
   Planes of the ends in the axial direction of the annular member 91 is designed into a wavy shape, such that adjacent members are nested with each other through a wave-shaped concave-convex structure to form a labyrinth structure.

According to the scheme of the embodiment of the disclosure, by means of the complex and tight connection between the annular members 91, the isolation of plasma can be ensured, the structural stability and gas tightness can be enhanced and the pollution and heat management problems can be reduced.

In an implementation, the chamber 6 is connected to the dielectric tube 4 by a first sinking platform, and a seal ring 3 is arranged between the first sinking platform and the dielectric tube 4.

In the embodiment of the disclosure, an upper portion of the chamber 6 is provided with a circular opening, the size of which is matched with that of the dielectric tube 4. An edge portion 61 of the chamber 6 beside the opening is provided with the first sinking platform, to which the second end of the dielectric tube 4 is connected. The sealing ring 3 is arranged between the first sinking platform and the dielectric tube 4. The first sinking platform is formed by sinking an upper surface of the edge portion 61 to the opposite lower surface by a certain distance.

In an implementation, the chamber 6 is connected to the liner 9 by a second sinking platform having a greater sinking depth than the first sinking platform.

In the embodiment of the disclosure, the edge portion 61 of the chamber 6 is further provided with the second sinking platform which is arranged on a side of the first sinking platform close to the center of the opening. The second sinking platform has a greater sinking depth than the first sinking platform, so that the lower end of the inner liner 9 exceeds the lower end of the dielectric tube 4. In this way, the dielectric tube 4 is better shielded to further prevent the dielectric tube 4 from being bombarded by plasma.

In an implementation, the protrusion 92 or the indentation is provided on a side close to a center of the dielectric tube 4.

In an implementation, the liner 9 is made of ceramic material.

The ceramic liner 9 is resistant to bombardment and chemical corrosion of the plasma to ensure that the dielectric tube 4 is not consumed. The ceramic material such as alumina (Al₂O₃), aluminum nitride (AlN), beryllium oxide (BeO) or silicon nitride (Si₃N₄) has excellent chemical stability. The ceramic material reacts less with hydrogen and other reactive gases (e.g., oxygen, fluorine, etc.), reducing recombination consumption, and maintaining high concentrations of active species in the plasma. In addition, the ceramic material has excellent electrical insulation performance, can effectively isolate the electric field interference between the plasma and the quartz cylinder, reduces the charge loss in the plasma, and improves the active substance concentration of the plasma.

In an implementation, the annular member 91 has a thickness ranging between 1 and 10 mm.

In the embodiment of the disclosure, an annular member 91 (hereinafter referred to as a ceramic ring) made of ceramic material is used as the liner 9, and the thickness thereof directly affects the penetration of the high-frequency magnetic field and the plasma generation efficiency. The thinner ceramic ring can reduce the loss of the high-frequency magnetic field in the material, thereby improving the energy coupling efficiency. In order to reduce the influence on the energy coupling efficiency of the coil 5, the thickness of the ceramic ring is as small as possible and can be 1˜10 mm. This allows more energy to be transferred into the plasma, increasing the plasma generation efficiency and the etch rate.

In an implementation, a gap between the annular member 91 and the inner wall of the dielectric tube 4 is less than a thickness of the plasma sheath.

In the embodiment of the disclosure, the plasma sheath refers to a thin layer of plasma region formed between the plasma and the inner wall of the dielectric tube 4. The thickness and stability of the plasma sheath can be influenced by controlling the gap between an outer wall of the ceramic ring and the inner wall of the dielectric tube 4. The smaller gap can prevent the plasma sheath from being too thick, reducing direct contact of the plasma with the dielectric tube 4. The gap between the outer wall of the ceramic ring and the inner wall of the dielectric tube 4 can be smaller than the thickness of the plasma sheath, for example, between 0.1 and 3 mm. The chance of the direct contact the plasma with the dielectric tube 4 can be effectively reduced, protecting the dielectric tube 4 from plasma bombardment and erosion. On the other hand, the thin ceramic ring and smaller gap help to better manage heat, reduce the risk of local overheating, and ensure that there is no interference between members and no particles produced due to the friction after the temperature of the member changes under the plasma condition.

According to the scheme of the embodiment of the disclosure, by the above technical means, the liner 9 can protect the dielectric tube 4 without significantly affecting the energy coupling efficiency of the coil 5, so that the etching efficiency is improved, the plasma is stabilized, the pollution is reduced and the maintenance cost of the apparatus is reduced.

The plasma generation apparatus according to any of the embodiments of the present disclosure may be applied to a plasma etching apparatus. As shown in FIG. 1, the plasma etching apparatus includes: a gas inlet line 1 and a vacuum pump 8.

The gas inlet line 1 is extended into the dielectric tube 4 through the cover plate 2, the dielectric tube 4 and the cover plate 2 are tightly connected, a supporting platform for placing a wafer 7 is provided inside the chamber 6, and a vacuum pump 8 is arranged at a bottom of the chamber 6. The cover plate 2, the dielectric tube 4 and the chamber 6 collectively define a vacuum chamber.

Radio frequency energy is fed into an antenna of the coil 5 and coupled to the vacuum chamber through a dielectric tube 4 to excite a process gas in the vacuum chamber 6 into plasma. For the hydrogen-containing process, the hydrogen gas forms active hydrogen atoms or hydrogen ions in the plasma, and these active species can chemically react with other gases or the sample surface so that the dielectric tube 4 can be consumed rapidly, resulting in increased cost.

Since the plasma excitation region is located far from the wafer 7, the plasma is excited and generated with a large power to ensure that the concentration of the excited-state component on the surface of the wafer 7 can be achieved.

Other configurations of the plasma etching apparatus of the above embodiments can be adopted by various technical solutions known by those skilled in the art now and in the future, and will not be described in detail herein.

In the description of the present specification, it should be understood that the orientations and positional relationships indicated by the terms such as “center”, “longitudinal”, “lateral”, “length”, “width”, “thickness”, “upper”, “lower”, “front”, “rear”, “left”, “right”, “vertical”, “horizontal”, “top”, “bottom”, “inner”, “outer”, “clockwise”, “counterclockwise”, “axial”, “radial” and “circumferential” are based on the orientations and positional relationships shown in the drawings, and are used merely for convenience of description and simplicity of description, but do not indicate or imply that the device or element referred to necessarily has a particular orientation, is constructed and operated in a particular orientation, and therefore should not be considered as limiting the present disclosure.

Furthermore, the terms “first” and “second” are used for descriptive purposes only and are not to be construed as indicating or implying relative importance or to implicitly indicate the number of technical features indicated. Thus, a feature defined as “first” or “second” may explicitly or implicitly include one or more of the features. In the description of the present disclosure, “a plurality” means two or more unless specifically limited otherwise.

In the present disclosure, unless otherwise explicitly defined, terms such as “mounted”, “joined”, “connected” and “fixed” are to be interpreted broadly. For example, such terms may refer to a fixed connection, a detachable connection, or an integral formation; they may denote mechanical, electrical, or communicative coupling; they may indicate direct connection or indirect connection via an intervening component; they may encompass internal communication or interaction between two elements. A person having ordinary skill in the art will understand the appropriate meaning of these terms in the context of the present disclosure based on the specific embodiment.

In the present disclosure, unless expressly stated or limited otherwise, the recitation of a first feature “on” or “under” a second feature may include the first and second features being in direct contact, or may include the first and second features being not in direct contact but in contact via another feature therebetween. Also, the recitation of the first feature “on”, “above” or “over” the second feature may include the first feature being right above or obliquely above the second feature, or may simply indicate that the first feature is at a higher level than the second feature. The recitation of the first feature “below”, “beneath,” and “under” the second feature may include the first feature being right under and obliquely under the second feature, or simply indicate that the first feature is at a lower level than the second feature.

The above disclosure provides many different embodiments or examples for implementing different structures of the disclosure. In order to simplify the present disclosure, specific example components and arrangements have been described above. Of course, they are merely examples and are not intended to limit the present disclosure. Moreover, the present disclosure may repeat reference numerals and/or reference signs in the various examples for the purpose of simplicity and clarity and they do not dictate a relationship between the various embodiments and/or arrangements discussed.

The above description is provided only for the specific embodiments of the present disclosure, but the scope of the present disclosure is not limited thereto. Any person skilled in the art can easily conceive the various changes or substitutions within the technical scope of the present disclosure, which should fall within the scope of the present disclosure. Accordingly, the scope of the present disclosure is defined by the appended claims.

What is claimed is:

1. A plasma generation apparatus comprising:
a dielectric tube (4), a first end of the dielectric tube (4) in an axial direction being connected with a cover plate (2) and a second end being in communication with a chamber (6);
a coil (5) wound outside the dielectric tube (4); and
a liner (9) disposed on an inner side of the dielectric tube (4), the liner (9) extending along an inner wall of the dielectric tube (4) such that the inner wall of the dielectric tube (4) is at least partially shielded by the liner (9) in a radial direction.

2. The plasma generation apparatus of claim 1, wherein the liner (9) is a cylindrical structure formed by stacking a plurality of annular members (91) in sequence in the axial direction of the dielectric tube (4), and a diameter of the annular members (91) is smaller than an inner diameter of the dielectric tube (4).

3. The plasma generation apparatus of claim 2, wherein two ends of the annular member (91) in the axial direction are provided with a protrusion (92) or an indentation having a matching shape of the protrusion, respectively; any two annular members (91) are connected with each other by engaging the protrusion (92) of one annular member with the indentation of the other annular member.

4. The plasma generation apparatus of claim 1, wherein the chamber (6) is connected to the dielectric tube (4) by a first sinking platform, and a sealing ring (3) is arranged between the first sinking platform and the dielectric tube (4).

5. The plasma generation apparatus of claim 4, wherein the chamber (6) is connected to the liner (9) by a second sinking platform having a greater sinking depth than the first sinking platform.

6. The plasma generation apparatus of claim 1, wherein the protrusion (92) or the indentation is provided on a side close to a center of the dielectric tube (4).

7. The plasma generation apparatus of claim 1, wherein the liner (9) is made of ceramic material.

8. The plasma generation apparatus of claim 2, wherein the annular member (91) has a thickness ranging between 1 and 10 mm.

9. The plasma generation apparatus of claim 2, wherein a gap between the annular member (91) and the inner wall of the dielectric tube (4) is smaller than a thickness of the plasma sheath.

10. A plasma etching apparatus comprising the plasma generation apparatus of claim 1.
